(19) United States
(12) Patent Application Publication
(10) Pub. No.: US 2019/0115911 A1
(43) Pub. Date: Apr. 18, 2019

(54) IN-VEHICLE SEMICONDUCTOR SWITCHING DEVICE AND IN-VEHICLE POWER SUPPLY DEVICE

(71) Applicants: AUTONETWORKS TECHNOLOGIES, LTD., Yokkaichi (JP); SUMITOMO WIRING SYSTEMS, LTD., Yokkaichi (JP); SUMITOMO ELECTRIC INDUSTRIES, LTD., Osaka (JP)

(72) Inventor: Byeongsu JEONG, Yokkaichi (JP)

(73) Assignees: AUTONETWORKS TECHNOLOGIES, LTD., Yokkaichi (JP); SUMITOMO WIRING SYSTEMS, LTD., Yokkaichi (JP); SUMITOMO ELECTRIC INDUSTRIES, LTD., Osaka (JP)

(21) Appl. No.: 16/161,778

(22) Filed: Oct. 16, 2018

(30) Foreign Application Priority Data
Oct. 18, 2017 (JP) 2017-201510

(51) Int. Cl. H03K 17/0812; H02M 1/08; H02M 1/32; H02M 3/158; H03K 17/082; H03K 17/16

(52) U.S. Cl. CPC H03K 17/08122; H02M 1/08; H02M 1/32; H02M 2001/0009; H03K 17/0822; H03K 17/162; H02M 3/1588

(57) ABSTRACT

A configuration is realized that enables ON/OFF operations to be performed stably and is unlikely to increase the switching time when driving an in-vehicle semiconductor switching device. An in-vehicle semiconductor switching device is turned ON and OFF by an ON signal and an OFF signal that are output from an in-vehicle driving circuit, and is switched between an ON state and an OFF state, at a position between a first conducting path and a second conducting path. Only some of a plurality of second terminals, which are electrically connected to a second semiconductor portion of a semiconductor switching element, are coupled to the second conducting path, and at least one of the remaining second terminals is coupled to a driving circuit-side conducting path (a conducting path electrically connected to the driving circuit.

### TECHNICAL FIELD

The present disclosure relates to an in-vehicle semiconductor switching device and an in-vehicle power supply device.

### BACKGROUND ART

Patent Document 1 discloses an example of an in-vehicle power supply device that includes a step-down DC/DC converter. This step-down DC/DC converter includes a driver for switching a high-side switching transistor based on a high-side pulse, and a lower-side power supply terminal of the driver is connected to a source of the high-side switching transistor. In the configuration in Patent Document 1, the high-side switching transistor forms an N-channel structure, and a boot strap circuit is provided to apply, to a gate of this switching transistor, a voltage that is higher than that applied to a drain and the source.

JP 2017-93158A and JP 2015-154591A are examples of related art.

Widely-known semiconductor switching devices (FETs, bipolar transistors etc.) for use in in-vehicle power supply devices include those with a package structure, in which a semiconductor chip is sealed with a sealing material such as a molding resin. For example, a semiconductor switching device Dv as shown in FIG. 8 has a semiconductor package Pa and peripheral wiring. The semiconductor package Pa is configured so that a semiconductor switching element Cp (semiconductor chip) that is configured as an FET (field effect transistor) element is covered with a sealing resin. This semiconductor package Pa includes a plurality of source terminals Sp1, SP2, and Sp3 that are electrically connected to a source of the semiconductor switching element Cp, a plurality of drain terminals Dp1, Dp2, Dp3, and Dp4 that are electrically connected to a drain, and a gate terminal Gp that is electrically connected to a gate. These terminals are exposed to the outside of the sealing resin.

In the case of using the semiconductor package Pa (FET) as a switch in a conducting path, usually, all of the plurality of source terminals Sp1, SP2, and Sp3 are coupled to a source-side conducting path L2, as shown in FIG. 8. In the case of driving the semiconductor package Pa (FET) using a gate driver, a source voltage can be input to the gate driver by connecting, to the gate driver, a driver-side conducting path L3 that is connected to the source-side conducting path L2, as shown in FIG. 8. Similar configurations are also disclosed in Patent Documents 1 and 2, which disclose configurations in which a source-side conducting path of a high-side FET is electrically connected to the gate driver.

However, in the case of employing the configuration shown in FIG. 8, all of the source terminals Sp1, Sp2, and Sp3 and all branch paths Br1, Br2, and Br3 are provided in a path Bs between the source of the semiconductor switching element Cp and the gate driver-side conducting path L3. As conceptually illustrated in FIG. 9, if it is assumed that an inductance component (parasitic inductance) in this path Bs (a path between the source of the semiconductor switching element Cp and a position P2) is Ls, a back electromotive force Ls·di/dt that is based on the inductance component Ls and a temporal change di/dt in a drain current i is generated in this path Bs. Accordingly, the potential difference Vdr between the gate of the semiconductor switching element Cp and the gate driver-side conducting path L3 has the value (Vdr=Vgs−L·di/dt) obtained by subtracting the back electromotive force (Ls·di/dt) from a voltage Vgs between the gate and the source of the semiconductor switching element Cp. Since the potential difference Vdr between the gate of the semiconductor switching element Cp and the gate driver-side conducting path L3 is thus affected by the back electromotive force that derives from the inductance component Ls (parasitic inductance), there is the concern that, when the semiconductor switching element Cp (FET element) is driven by the gate driver, the switching time will increase, or the stability of ON/OFF operations will be lost.

### SUMMARY

The present disclosure has been made to solve at least one of the aforementioned problems, and aims to realize a configuration that enables ON/OFF operations to be performed stably and is unlikely to increase the switching time when driving an in-vehicle semiconductor switching device.

An in-vehicle semiconductor switching device, which is a part of the present disclosure, is an in-vehicle semiconductor switching device that is turned ON and OFF by an ON signal and an OFF signal that is output from an in-vehicle driving circuit, and is switched between an ON state and an OFF state, at a position between a first conducting path and a second conducting path, the semiconductor switching device including:

a semiconductor switching element including a first semiconductor portion having a semiconductor material, a second semiconductor portion arranged at a position different from the position of the first semiconductor portion and having a semiconductor material, and an input portion to which the ON signal and the OFF signal are input from the driving circuit, wherein the semiconductor switching element enters the ON state if the ON signal is input to the input portion, and enters the OFF state if the OFF signal is input to the input portion;

at least one first terminal electrically connected to the first semiconductor portion;

a plurality of second terminals electrically connected to the second semiconductor portion; and

at least one third terminal electrically connected to the input portion,

wherein the first terminal is connected to the first conducting path, and

only some of the plurality of second terminals are coupled to the second conducting path, and at least one of the remaining second terminals is coupled to a driving circuit-side conducting path electrically connected to the driving circuit.

An in-vehicle power supply device, which is a part of the present disclosure, includes:

the above-described in-vehicle semiconductor switching device; and

a voltage conversion unit that boosts or drops a voltage applied to one conducting path and applies the boosted or dropped voltage to another conducting path, in accordance with a switching operation of one or more switching units,

wherein at least one of the switching units is constituted by the semiconductor switching device.

In the present embodiment, the semiconductor switching device is turned on and off by an ON signal and an OFF signal that are output from the driving circuit, and switches between the ON state and the OFF state, at a position between the first conducting path and the second conducting path. Only some of the pluralities of second terminals, which are electrically connected to the second semiconductor portion, are coupled to the second conducting path, and at least one of the remaining second terminals is coupled to the driving circuit-side conducting path (a conducting path that is electrically connected to the driving circuit. Due to this this configuration, a section through which a large current flows in a path between the second semiconductor portion and the driving circuit-side conducting path is made shorter, and a back electromotive force that derives from parasitic inductance can be further reduced. Accordingly, when driving the in-vehicle semiconductor switching device, ON/OFF operations can readily be performed stably, and the switching time is unlikely to increase.

### BRIEF DESCRIPTION OF THE DRAWINGS

FIG. 1 is an illustrative diagram schematically illustrating an example of an in-vehicle semiconductor switching device according to Embodiment 1.

FIG. 2 is a plan view schematically illustrating an example of a semiconductor package that constitutes the semiconductor switching device in FIG. 1.

FIG. 3 is a side view schematically illustrating an example of a structure in which the semiconductor package in FIG. 2 is attached to a substrate.

FIG. 4 is a conceptual cross-sectional view conceptually illustrating an internal structure of a semiconductor switching element in the semiconductor package in FIG. 2.

FIG. 5 is a circuit diagram illustrating an equivalent circuit of the semiconductor switching device in FIG. 1 that reflects parasitic inductance.

FIG. 6 is a circuit diagram schematically illustrating an example of an in-vehicle power supply system equipped with an in-vehicle power supply device that includes the semiconductor switching device in FIG. 1, and other components.

FIG. 7 is a circuit diagram illustrating an example of a connection configuration of the semiconductor switching device, a driving circuit, and so on in the in-vehicle power supply device shown in FIG. 6.

FIG. 8 is an illustrative diagram schematically illustrating an example of a semiconductor switching device in a comparative example.

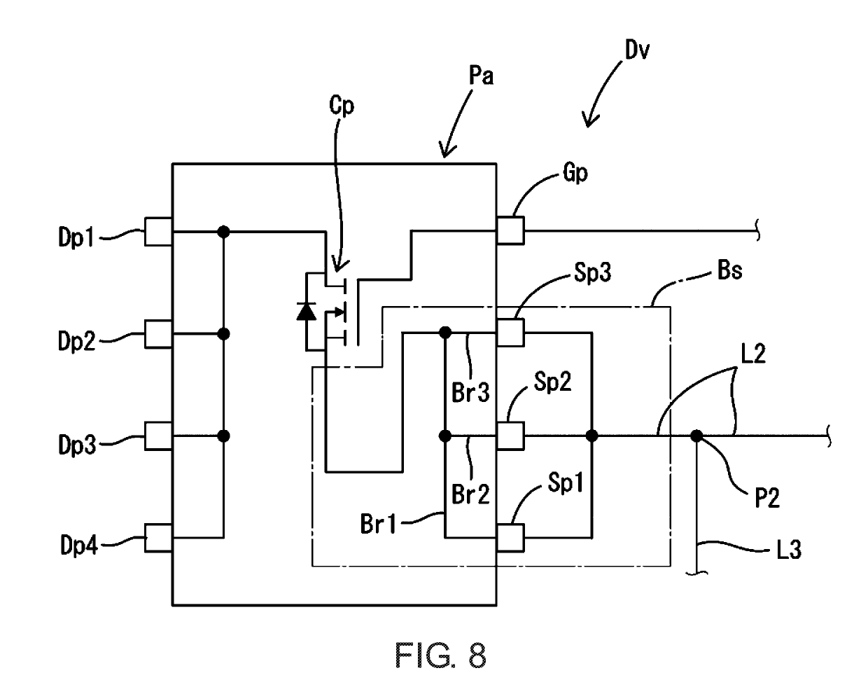

FIG. 9 is a circuit diagram illustrating an equivalent circuit of the semiconductor switching device in FIG. 8 that reflects parasitic inductance.

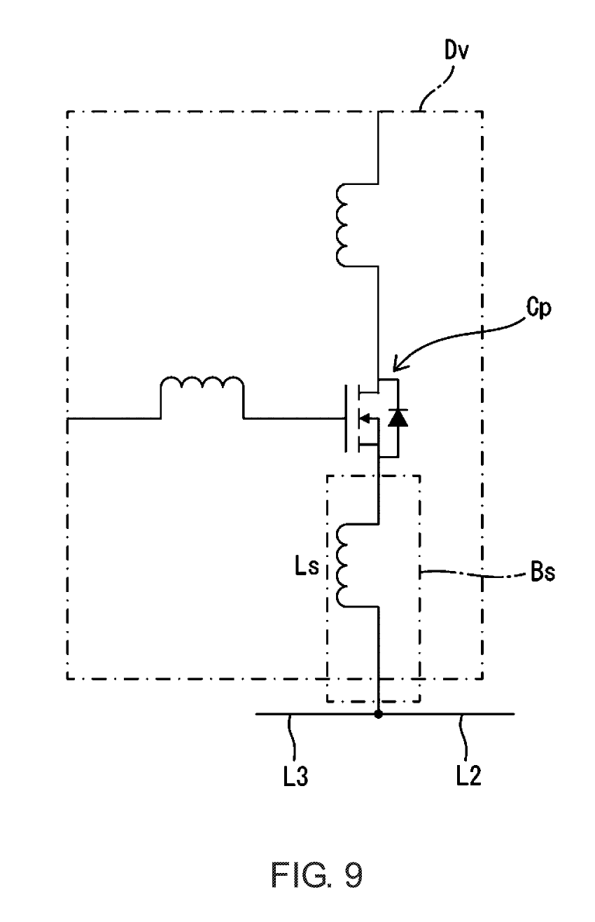

FIG. 10 is an illustrative diagram schematically illustrating an example of an in-vehicle semiconductor switching device according to another embodiment.

### EMBODIMENTS

Preferable examples will now be described.

The plurality of second terminals may be formed with the same conductive member, and may be integrally coupled to each other.

In this semiconductor switching device, although the plurality of second terminals are formed with the same conductive member and are integrally coupled to each other, a section through which a large current flows in the path between the second semiconductor portion and the driving circuit-side conducting path is made shorter, and a back electromotive force that derives from parasitic inductance can be further reduced.

In the above semiconductor switching device, the semiconductor switching element may have a third semiconductor portion provided between the first semiconductor portion and the second semiconductor portion. The semiconductor switching element may be configured so that a current flows between the first semiconductor portion and the second semiconductor portion via the third semiconductor portion if the ON signal is input to the input portion, and no current flows via the third semiconductor portion if the OFF signal is input to the input portion. Out of the plurality of second terminals, a terminal whose path length to the third semiconductor portion is shortest may be coupled to the driving circuit-side conducting path.

If the terminal whose path length to the third semiconductor portion is shortest, out of the plurality of second terminals, is thus coupled to the driving circuit-side conducting path, the path from the second terminal coupled to the driving circuit-side conducting path to the third semiconductor portion is made shorter. Accordingly, in this semiconductor switching device, parasitic inductance in the path from the second terminal coupled to the driving circuit-side conducting path to the third semiconductor portion is further reduced. This configuration is more advantageous in stabilizing ON/OFF operations and reducing the switching time.

Out of the plurality of second terminals, the number of terminals coupled to the second conducting path may be greater than the number of terminals coupled to the driving circuit-side conducting path.

In the thus-configured semiconductor switching device, a back electromotive force that drives from parasitic inductance can be reduced in the path between the second semiconductor portion and the driving circuit-side conducting path, and meanwhile, parasitic inductance between the second semiconductor portion and the second conducting path can be further reduced.

Out of the plurality of second terminals, the number of terminals coupled to the driving circuit-side conducting path may be greater than the number of terminals coupled to the second conducting path.

In the thus-configured semiconductor switching device, the shortening of a path through which a large current flows in the path between the second semiconductor portion and the driving circuit-side conducting path can suppress a back electromotive force that drives from parasitic inductance. Moreover, the configuration in which more second terminals are coupled to the driving circuit-side conducting path can further reduce parasitic inductance between the second semiconductor portion and the driving circuit-side conducting path.

In the above-described in-vehicle power supply device, the voltage conversion unit may be configured so that a high-side switching unit, out of the switching units, is connected to a low-side switching unit, out of the switching units, or a diode, to each other in series between a ground and one of the one conducting path and the other conducting path. The high-side switching unit may be constituted by the semiconductor switching device.

In the voltage conversion unit in the in-vehicle power supply device, the switching time at the high-side switching unit is likely to increase due to parasitic inductance. For this reason, application of the above-described semiconductor switching device to the high-side switching unit is more effective.

### Embodiment 1

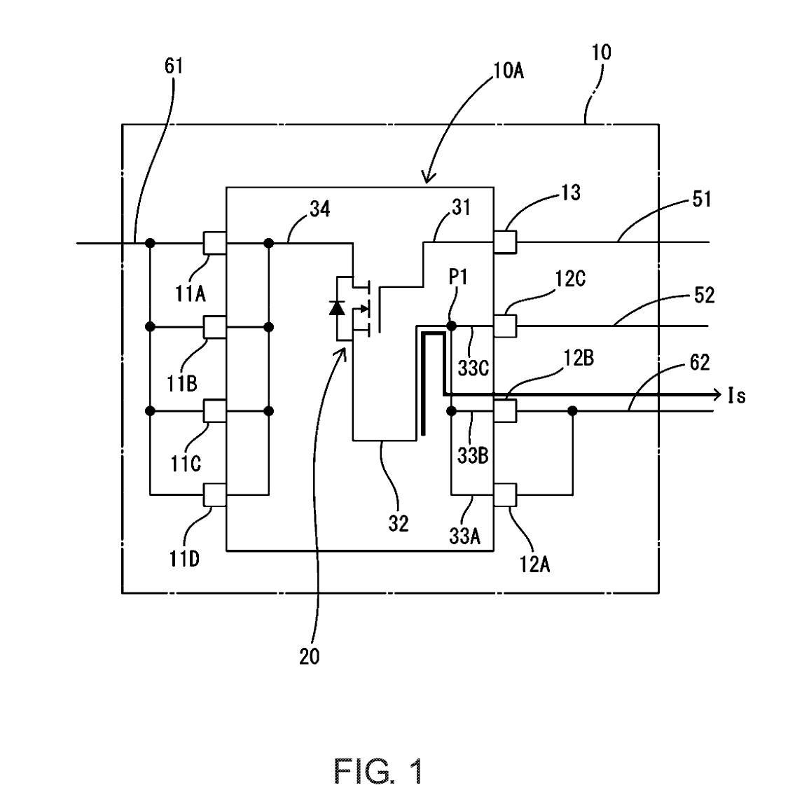

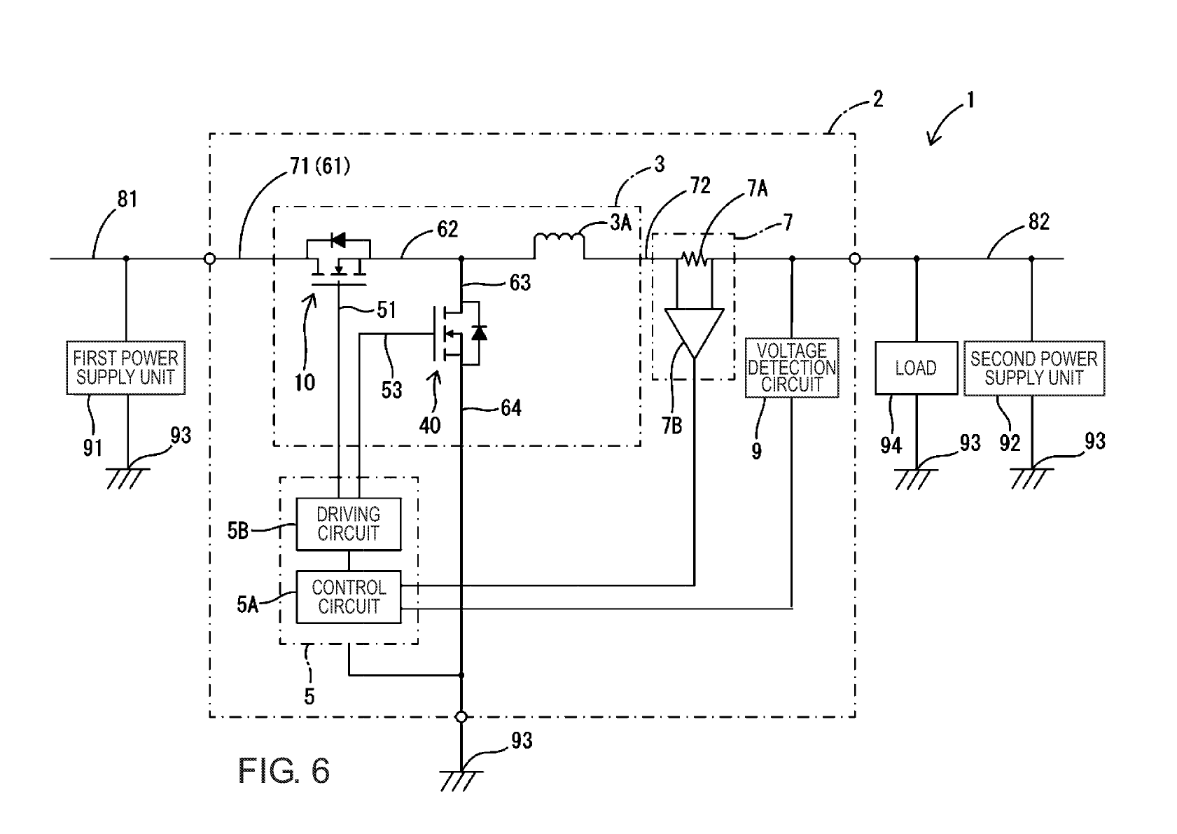

Hereinafter, Embodiment 1 will be described. A semiconductor switching device 10 shown in FIGS. 1 to 3 is used as, for example, a switching unit (e.g. a high-side switching unit) in a voltage conversion unit 3 in a later-described in-vehicle power supply device 2 (hereinafter also referred to as “power supply device 2”), which is shown in FIG. 6. In the example in FIG. 6, the semiconductor switching device 10 is turned ON and OFF by an ON signal and an OFF signal that are output from an in-vehicle driving circuit 5B (hereinafter also referred to as “driving circuit 5B”), and switches between an ON state and an OFF state, at a position between a first conducting path 61 and a second conducting path 62. Note that the configuration and operation of the power supply device 2 will be described later.

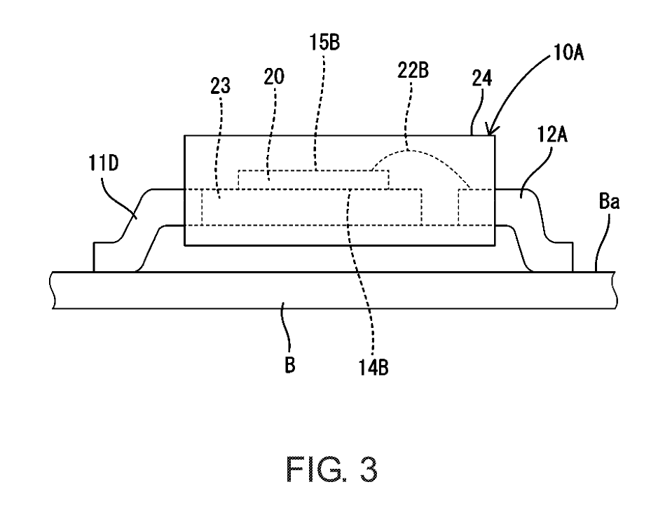

As shown in FIGS. 1 to 3, the semiconductor switching device 10 includes a semiconductor package 10A, which is formed as an SOP (Small Outline Package), for example, and a wiring portion (including portions of second conducting paths 62 and a portion of a driving circuit-side conducting path 52) that is coupled to terminals of the semiconductor package 10A. The semiconductor package 10A includes a semiconductor switching element 20, a plurality of first terminals 11A, 11B, 11C, and 11D, a plurality of second terminals 12A, 12B, and 12C, and a third terminal 13. In the example in FIG. 3, the semiconductor package 10A is surface-mounted on a substrate B. The plurality of first terminals 11A, 11B, 11C, and 11D, the plurality of second terminals 12A, 12B, and 12C, and the third terminal 13 are soldered to a wiring pattern formed on a surface portion Ba of the substrate B.

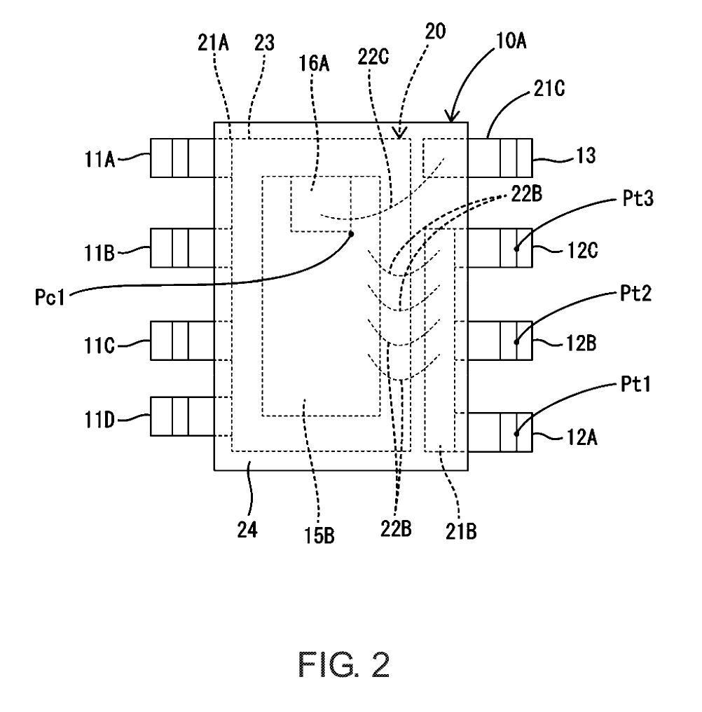

As shown in FIGS. 2 and 3, the semiconductor package 10A includes a plurality of lead members 21A, 21B, and 21C, which are made of a metallic material. A die pad 23 is provided at the center of the lead member 21A. A semiconductor switching element 20, which is configured as a semiconductor chip, is mounted on the die pad 23. A package structure is formed in which the die pad 23 and the semiconductor switching element 20 are covered with a sealing resin 24, and the lead members 21A, 21B, and 21C are partially exposed to the outside of the sealing resin 24.

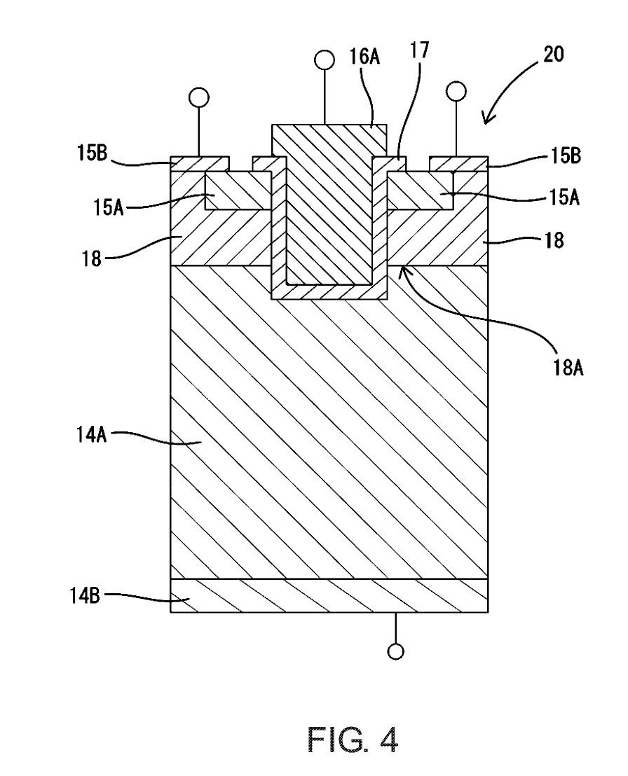

For example, the semiconductor switching element 20 is constituted by a semiconductor chip that is configured as an FET (field effect transistor), and has a cross-sectional structure that is schematically shown in FIG. 4. As shown in FIG. 4, the semiconductor switching element 20 includes a first semiconductor portion 14A, which contains a semiconductor material, a second semiconductor portion 15A, which is arranged at a position different from that of the first semiconductor portion 14A and contains a semiconductor material, and an input portion 16A, to which the ON signal and the OFF signal are input from the driving circuit 5B. The first semiconductor portion 14A is an N-type semiconductor region that functions as a drain of the FET, and the second semiconductor portion 15A is an N-type semiconductor region that functions as a source of the FET. A P-type semiconductor region 18 is formed between the first semiconductor portion 14A and the second semiconductor portion 15A, and a portion of the P-type semiconductor region functions as a channel of the FET. The portion of the P-type semiconductor region 18 that functions as a channel serves as a third semiconductor portion 18A. The input portion 16A functions as a gate electrode.

A source electrode 15B, which is in contact with the second semiconductor portion 15A and is formed as a conductive electrode layer, is provided on the surface side of the semiconductor switching element 20 (semiconductor chip). Also, the input portion 16A (gate electrode), which is formed as a conductive electrode layer, is provided at a position out of the region of the source electrode 15B on the surface side of the semiconductor switching element 20 (semiconductor chip). A drain electrode 14B, which is in contact with the first semiconductor portion 14A, is provided on the back side of the semiconductor switching element 20. The drain electrode 14B is pressure-bonded to the die pad 23. An insulating film 17 is provided around the input portion 16A (gate electrode) so as to insulate the input portion 16A from the first semiconductor portion 14A, the second semiconductor portion 15A, and the P-type semiconductor region 18.

The die pad 23, to which the drain electrode 14B is joined, forms a part of the lead member 21A, and is integrally formed with the plurality of first terminals 11A, 11B, 11C, and 11D. The first terminals 11A, 11B, 11C, and 11D are electrically connected to the first semiconductor portion 14A. The input portion 16A, which is configured as a gate electrode, is electrically connected to the lead member 21C via a bonding wire 22C. In the example shown in FIG. 2 and other diagrams, the lead member 21C is configured as the third terminal 13 (a terminal that is electrically connected to the input portion 16A. The source electrode 15B is electrically connected to the lead member 21B via a plurality of bonding wires 22B. The lead member 21B is a metallic member on which the plurality of second terminals 12A, 12B, and 12C are formed. The second terminals 12A, 12B, and 12C are electrically connected to the second semiconductor portion 15A. In the example shown in FIG. 2 and other diagrams, the second terminals 12A, 12B, and 12C are formed with the same conductive member (a metallic member that constitutes the lead member 21B), and are integrally coupled to each other. In the example shown in FIGS. 1 to 3, the plurality of first terminals 11A, 11B, 11C, and 11D, the plurality of second terminals 12A, 12B, and 12C, and the third terminal 13 are partially exposed to the outside of the sealing resin 24.

In the example in FIG. 1, all of the plurality of first terminals 11A, 11B, 11C, and 11D are electrically connected to the first conducting path 61 while being coupled thereto. The first conducting path 61 has a first wiring pattern that is formed on the surface portion Ba of the substrate B shown in FIG. 3, for example, and all of the plurality of first terminals 11A, 11B, 11C, and 11D are soldered to the first wiring pattern.

In the example in FIG. 1, only some (the second terminals 12A and 12B) of the plurality of second terminals 12A, 12B, and 12C are coupled to the second conducting path 62, and the remaining one (the second terminal 12C) is coupled to the driving circuit-side conducting path 52, which is electrically connected to the driving circuit 5B. The second conducting path 62 has a second wiring pattern that is formed on the surface portion Ba of the substrate B, for example, and the second terminals 12A and 12B are soldered to the second wiring pattern. The driving circuit-side conducting path 52 has a third wiring pattern that is formed on the surface portion Ba of the substrate B shown in FIG. 3, and the second terminal 12C is soldered to the third wiring pattern. In the example in FIG. 1, the number of terminals that are coupled to the second conducting path 62, out of the plurality of second terminals 12A, 12B, and 12C, is greater than the number of second terminals that are coupled to the driving circuit-side conducting path 52.

As shown in FIG. 1, the semiconductor package 10A includes a shared conducting path 32 that is electrically connected, on one side, to the second semiconductor portion 15A, and a plurality of branch conducting paths 33A, 33B, and 33C, which are formed as a result of the shared conducting path 32 branching on the other side. The second terminals 12A, 12B, and are provided in the branch conducting paths 33A, 33B, and 33C, respectively. Out of the plurality of second terminals 12A, 12B, and 12C, the terminal (the second terminal 12C) whose path length to the shared conducting path 32 is shortest is coupled to the driving circuit-side conducting path 52. Furthermore, out of the plurality of second terminals 12A, 12B, and 12C, the terminal whose path length to the third semiconductor portion 18A is shortest (i.e. the terminal whose path length to the input portion 16A is shortest), namely the second terminal 12C may be coupled to the driving circuit-side conducting path 52. Specifically, when comparing between the shortest current path (first path) through which a current flows from the third semiconductor portion 18A (channel region) to the second terminal 12A via the second semiconductor portion 15A (source region) and the bonding wire 22B, the shortest current path (second path) through which a current flows from the third semiconductor portion 18A to the second terminal 12B via the second semiconductor portion 15A and the bonding wire 22B, and the shortest current path (third path) through which a current flows from the third semiconductor portion 18A (channel region) to the second terminal 12C via the second semiconductor portion 15A (source region) and the bonding wire 22B, the third path is the shortest, and the second terminal 12C, which is a terminal of this third path, is coupled to the driving circuit-side conducting path 52. Specifically, when it is assumed that the center position in a joint face of the second terminal 12A that is to be joined to the second conducting path 62 is Pt1, the center position in a joint face of the second terminal 12B that is to be joined to the second conducting path 62 is Pt2, and the center position in a joint face of the second terminal 12C that is to be joined to the driving circuit-side conducting path 52 is Pt3, the shortest path through which a current flows between an end portion Pc1 (a position closest to the bonding wire 22B, which is a conductive member) of the third semiconductor portion 18A and the position Pt1 via the bonding wire 22B is the first path, the shortest path through which a current flows between the end portion Pc1 and the position Pt2 via the bonding wire 22B is the second path, and the shortest path through which a current flows between the end portion Pc1 and the position Pt3 via the bonding wire 22B is the third path. The third path is the shortest.

In the example in FIG. 1, the third terminal 13 is coupled to a signal line 51, and the input portion 16A (gate electrode) and the signal line 51 are electrically connected to each other. The signal line 51 is a wiring portion to which the ON signal or the OFF signal is applied by the driving circuit 5B, and has a wiring pattern for the signal line that is formed on the surface portion Ba of the substrate B shown in FIG. 3. The third terminal 13 is soldered to this wiring pattern for the signal line.

In the thus-configured semiconductor switching device 10, the semiconductor switching element 20 enters the ON state if the ON signal is input to the input portion 16A (gate electrode), and the semiconductor switching element 20 enters the OFF state if the OFF signal is input to the input portion 16A. The ON signal is a signal with which at least a voltage Vgs between the gate and the source of the semiconductor switching element 20 is greater than a gate threshold voltage Vgs(th), and is, for example, an H-level signal of a predetermined voltage capable of switching the semiconductor switching element 20 to the ON state. The OFF signal is a signal with which at least the voltage Vgs between the gate and the source of the semiconductor switching element 20 is smaller than the gate threshold voltage Vgs(th), and is, for example, an L-level signal of a predetermined voltage capable of switching the semiconductor switching element 20 to the OFF state. For example, if the ON signal is input to the input portion 16A (gate electrode) by the later-described driving circuit 5B (FIG. 6), the third semiconductor portion 18A, which is provided between the first semiconductor portion 14A (drain region) and the second semiconductor portion 15A (source region), functions as a channel region, and a current flows between the first semiconductor portion 14A and the second semiconductor portion 15A via the third semiconductor portion 18A. On the other hand, if the OFF signal is input to the input portion 16A (gate electrode), the third semiconductor portion 18A does not function as a channel region, and no current flows between the first semiconductor portion 14A and the second semiconductor portion 15A via the third semiconductor portion 18A.

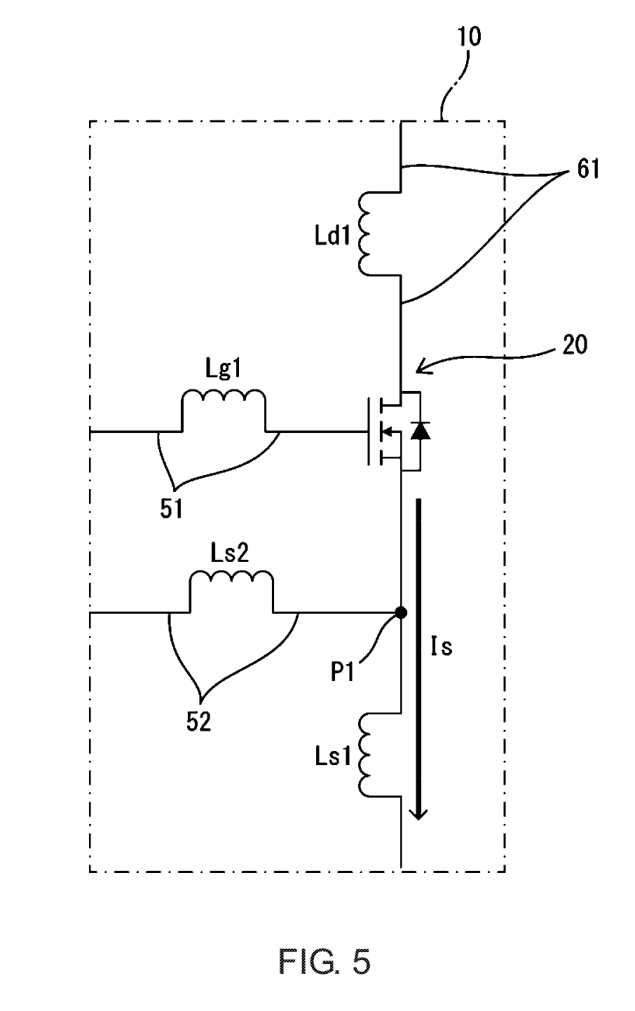

As shown in FIGS. 1 and 2, in the semiconductor switching device 10, only some (the second terminals 12A and 12B) of the plurality of second terminals 12A, 12B, and 12C that are electrically connected to the second semiconductor portion 15A are coupled to the second conducting path 62, and the remaining one (the second terminal 12C) of them is coupled to the driving circuit-side conducting path 52. Due to this configuration, if, as shown in FIGS. 1 and 5, a current Is flows between the first conducting path 61 and the second conducting path 62 as a result of an ON operation of the semiconductor switching element 20, the path through which the current Is flows in the path between the second semiconductor portion 15A and the driving circuit-side conducting path 52 is only the shared conducting path 32. Thus, the section through which a large current flows is made shorter, and a back electromotive force that derives from parasitic inductance can be further reduced in this path. Accordingly, when a voltage on the driving circuit-side conducting path 52 is input to the driving circuit 5B to drive the semiconductor switching device 10, ON/OFF operations are likely to be performed stably, and the switching time is unlikely to increase. Note that, in FIG. 5, the parasitic inductance on the second conducting path 62 side relative to the position P1 (an end portion of the shared conducting path 32) is Ls1, and the parasitic inductance on the driving circuit-side conducting path 52 side relative to the position P1 is Ls2. The parasitic inductance on the signal line 51 side relative to the input portion 16A (gate electrode) is Lg1, and the parasitic inductance on the first conducting path 61 side relative to the first semiconductor portion 14A (drain region) is Ld1.

Next, a description will be given of the power supply device 2 that uses the above-described semiconductor switching device 10. The in-vehicle power supply system 1 shown in FIG. 6 is configured as a system that includes a first power supply unit 91 and a second power supply unit 92, which are configured as in-vehicle power supply units, and a power supply device 2, which is configured as a step-down DCDC converter, and that can supply power to a load 94 that is mounted on a vehicle. The load 94 is a known in-vehicle electric component, the type and number of which are not limited.

The first power supply unit 91 is constituted by, for example, a lithium-ion battery or an accumulator means such as a double layer capacitor, and generates a first predetermined voltage. A high-potential terminal of the first power supply unit 91 is electrically connected to a wiring portion 81 that is provided in the vehicle, and the first power supply unit 91 applies a predetermined voltage to the wiring portion 81. The wiring portion 81 is electrically connected to one conducting path 71 (hereinafter also referred to simply as “conducting path 71”) of the power supply device 2. The conducting path 71 functions as the aforementioned first conducting path 61.

The second power supply unit 92 is constituted by, for example, an accumulator means such as a lead storage battery, and generates a second predetermined voltage that is lower than the first predetermined voltage generated by the first power supply unit 91. A high-potential terminal of the second power supply unit 92 is electrically connected to a wiring portion 82 that is provided in the vehicle, and the second power supply unit 92 applies a predetermined voltage to the wiring portion 82. The wiring portion 82 is electrically connected to another conducting path 72 (hereinafter also referred to simply as “conducting path 72”) of the power supply device 2.

A ground 93 is configured as a ground in the vehicle, and is kept at a fixed ground voltage (0 v). This ground is electrically connected to a low-potential terminal of the first power supply unit 91 and a low-potential terminal of the second power supply unit 92, and is also electrically connected to a source of a later-described semiconductor switching device 40.

The power supply device 2 is configured as an in-vehicle step-down DCDC converter, and is configured to lower a DC voltage applied to an input-side conducting path (conducting path 71) and output the lowered DC voltage to an output-side conducting path (conducting path 72). The power supply device 2 mainly includes the conducting path 71, the conducting path 72, the voltage conversion unit 3, a control unit 5, a voltage detection circuit 9, a current detection unit 7, and so on.

The input-side conducting path 71 is configured as a primary (high-voltage) power supply line to which a relatively high voltage is applied, and is electrically connected to the high-potential terminal of the first power supply unit 91 via the wiring portion 81. A predetermined DC voltage is applied to the conducting path 71 from the first power supply unit 91. The output-side conducting path 72 is configured as a secondary (low-voltage) power supply line to which a relatively low voltage is applied, and is electrically connected to a high-potential terminal of the second power supply unit 92 via the wiring portion 82. A DC voltage smaller than the output voltage of the first power supply unit 91 is applied to the conducting path 72 from the second power supply unit 92.

The voltage conversion unit 3 is provided between the conducting path 71 and the conducting path 72, and includes a first switching unit on a high side that is constituted by the above-described semiconductor switching device 10 (hereinafter also referred to as “switching device 10”) that is connected to the conducting path 71, a second switching unit on a low side that is constituted by the semiconductor switching device 40 (hereinafter also referred to as “switching device 40”) that is connected between the conducting path 71 and the ground 93 (a conducting path that is kept at a predetermined reference potential lower than the potential in the conducting path 71), and an inductor 3A that is electrically connected between the conducting path 72 and the switching devices 10 and 40. In this example, the first switching unit on the high side (switching device 10) and the second switching unit on the low side (switching device 40) are connected in series between the one conducting path 71 and the ground 93. The voltage conversion unit 3 constitutes a main part of the step-down DCDC converter using a switching method, and can perform a step-down operation to lower the voltage applied to the conducting path 71 by switching the switching device 10 between the ON operation and the OFF operation, and output the lowered voltage to the conducting path 72.

Both the switching devices 10 and 40 include a semiconductor switching element (semiconductor chip) that is configured as an N-channel MOSFET. One end of the conducting path 71 (the first conducting path 61) is electrically connected to a drain of the high-side switching device 10, and the second conducting path 62 is electrically connected to a source of the switching device 10. Also, a drain of the low-side switching device 40 and one end of the inductor 3A are electrically connected to the source of the switching device 10 via the second conducting path 62. The signal line 51 is electrically connected to a gate of the switching device 10, and the ON signal (driving signal) and the OFF signal (non-driving signal) from the driving circuit 5B (gate driver) are input to this gate. The switching device 10 is switched between the ON state and the OFF state in accordance with the signal from the driving circuit 5B.

The drain of the lower-side switching device 40 is electrically connected to the first conducting path 63, and is electrically connected to the source of the switching device 10 and one end of the inductor 3A via the first conducting path 63. A source of the switching device 40 is electrically connected to a second conducting path 64, and is electrically connected to the ground 93 via the second conducting path 64. A signal line 53 is electrically connected to a gate of the switching device 40, and the ON signal (driving signal) and the OFF signal (non-driving signal) from the driving circuit 5B (gate driver) are input to this gate. The switching device 40 is switched between the ON state and the OFF state in accordance with the signal from the driving circuit 5B.

One end of the inductor 3A is connected to a connecting portion between the switching device 10 and the switching device 40, and the other end is connected to the conducting path 72 (specifically, a portion of the conducting path 72 on the voltage conversion unit 3 side relative to the current detection unit 7). The current detection unit 7 has a resistor 7A and a differential amplifier 7B, and inputs a value that indicates the current flowing through the conducting path 72 (specifically, an analog voltage corresponding to the value of the current flowing through the conducting path 72) to the control circuit 5A. The voltage detection circuit 9 is connected to the conducting path 72, and inputs a value corresponding to the voltage on the conducting path 72 to the control circuit 5A. The voltage detection circuit 9 need only be a known voltage detection circuit capable of inputting a value that indicates the voltage on the conducting path 72 to the control circuit 5A, and is configured as, for example, a voltage division circuit that divides the voltage on the conducting path 72 and inputs the divided voltage to the control circuit 5A.

The control unit 5 includes the control circuit 5A and the driving circuit 5B. The control circuit 5A is configured as a microcomputer, for example, and includes a CPU for performing various kinds of computing processing, a ROM for storing information such as a program, a RAM for temporarily storing generated information, an A/D converter for converting an input analog voltage to a digital value, and so on. When causing the voltage conversion unit 3 to perform a step-down operation, the control circuit 5A performs feedback operation so as to bring the voltage applied to the conducting path 72 close to a set target value while detecting the voltage on the conducting path 72 using the voltage detection circuit 9, and generates a PWM signal.

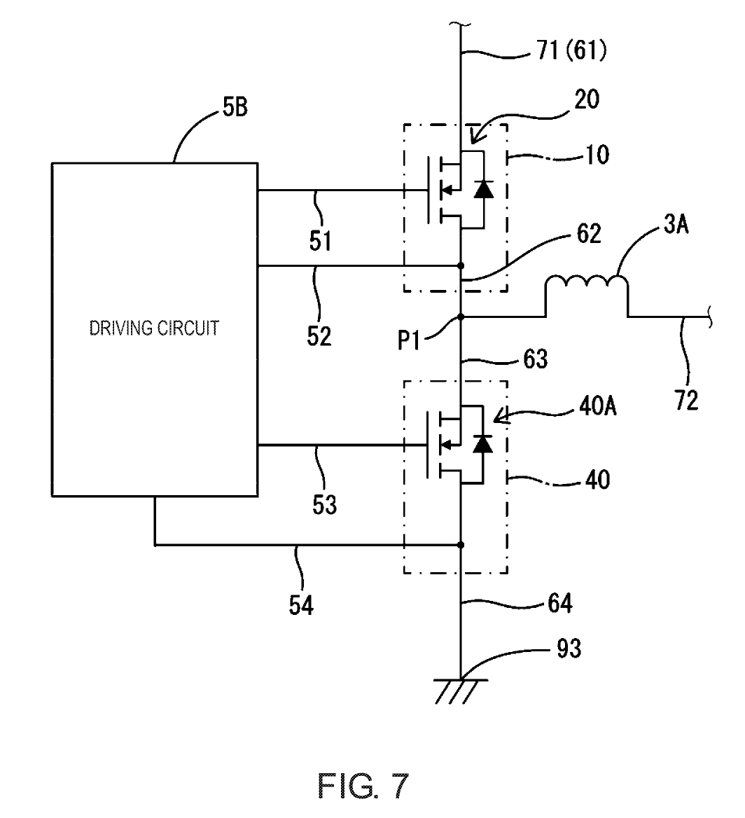

The driving circuit 5B shown in FIGS. 6 and 7 is configured as a gate driver, and applies ON signals for alternately turning ON the switching devices 10 and 40 in respective control cycles, to the gates of the switching devices 10 and 40 based on a PWM signal given from the control circuit 5A. The ON signal applied to the gate of the switching device 10 has a phase that is substantially inverted relative to that of the ON signal applied to the gate of the switching device 40, and a so-called dead time is secured for the ON signal applied to the gate of the switching device 10. As shown in FIG. 7, the driving circuit 5B receives a voltage input from the driving circuit-side conducting path 52 that is electrically connected to a conducting path between the source of the semiconductor switching element 20 and a drain of a semiconductor switching element 40A, and includes an upper-arm circuit that generates an ON signal for turning ON the semiconductor switching element 20 and an OFF signal for turning OFF the semiconductor switching element 20 based on the voltage input to the driving circuit-side conducting path 52. The driving circuit 5B also receives a voltage input from a driving circuit-side conducting path 54 that is electrically connected to a conducting path between a source of the semiconductor switching element 40A and the ground 93, and includes a lower-arm circuit that generates an ON signal for turning ON the semiconductor switching element 40A and an OFF signal for turning OFF the semiconductor switching element 40A based on the voltage input to the driving circuit-side conducting path 54. Note that in FIG. 6, the driving circuit-side conducting paths 52 and 54, and so on are omitted.

The thus-configured power supply device 2 functions as a step-down DCDC converter that uses synchronous rectification. The power supply device 2 lowers a DC voltage applied to the conducting path 71 and outputs the lowered DC voltage to the conducting path 72 by switching ON and OFF the high-side switching device 10 and also complementarily switching between an ON operation and an OFF operation of the low-side switching device 40 in synchronization with the operation of the high-side switching device 10. The output voltage of the conducting path 72 is determined in accordance with the duty ratio of the PWM signal applied to the gate of the switching device 10.

Although an example has been described above in which the semiconductor switching device 10 is provided as the high-side switching unit of the power supply device 2, the low-side switching unit may also have a connection configuration similar to that of the semiconductor switching device 10. For example, if the semiconductor switching device 40 in the configuration in FIG. 6 is configured similarly to the semiconductor switching device 10 shown in FIGS. 1 to 3 and other diagrams, the semiconductor switching device 40 can be configured as shown in FIG. 7. In this case, a configuration may be employed in which the semiconductor switching element 40A is configured similarly to the semiconductor switching element 20, a gate terminal (a terminal similar to the third terminal 13) provided in the semiconductor switching device 40 is joined to the signal line 53 that extends from the driving circuit 5B, a drain terminal (a terminal similar to the first terminals 11A, 11B, 11C, and 11D) provided in the semiconductor switching device 40 is joined to the first conducting path 63, some (terminals similar to the second terminals 12A and 12B) of source terminals provided in the semiconductor switching device 40 are joined to the second conducting path 64, and the remaining source terminal (a terminal similar to the second terminal 12C) provided in the semiconductor switching device 40 is joined to the driving circuit-side conducting path 54.

Examples of the effects of this configuration will be described below. The semiconductor switching device 10 is turned ON and OFF by the ON signal and the OFF signal that is output from the driving circuit 5B, and is switched between the ON state and the OFF state, at a position between the first conducting path 61 and the second conducting path 62. Only some of the plurality of second terminals 12A, 12B, and 12C that are electrically connected to the second semiconductor portion 15A are coupled to the second conducting path 62, and at least one of the remaining second terminals is coupled to the driving circuit-side conducting path 52 (a conducting path electrically connected to the driving circuit 5B). Due to this configuration, a section through which a large current flows in the path between the second semiconductor portion 15A and the driving circuit-side conducting path 52 is made shorter, and a back electromotive force that derives from parasitic inductance can be further reduced. Accordingly, when driving the semiconductor switch device 10, ON/OFF operations are likely to be performed stably, and the switching time is unlikely to increase.

In the semiconductor switching device 10 in which the plurality of second terminals 12A, 12B, and 12C are formed with the same conductive member, and are integrally coupled to each other, a section in the path between the second semiconductor portion 15A and the driving circuit-side conducting path 52 that is significantly affected by parasitic inductance (i.e. a section through which a large current may flow) can be made shorter, and a back electromotive force that derives from parasitic inductance can be further reduced.

The semiconductor switching device 10 includes the shared conducting path 32 that is electrically connected, on one side, to the second semiconductor portion 15A, and the plurality of branch conducting paths 33A, 33B, and 33C, which are formed as a result of the shared conducting path 32 branching on the other side. The plurality of second terminals 12A, 12B, and 12C are provided in the plurality of branch conducting paths 33A, 33B, and 33C, respectively. Out of the plurality of second terminals 12A, 12B, and 12C, the terminal whose path length to the shared conducting path 32 is shortest is coupled to the driving circuit-side conducting path 52. As mentioned above, a back electromotive force that derives from parasitic inductance is reduced by forming, as the shared conducting path 32, a short section through which a large current flows in the path between the second semiconductor portion 15A and the driving circuit-side conducting path 52. Moreover, since the path from the terminal coupled to the driving circuit-side conducting path 52, out of the second terminals 12A, 12B, and 12C, to the shared conducting path 32 is made shorter, parasitic inductance in this path can be further reduced. Accordingly, this semiconductor switching device 10 has a configuration that is further advantageous in stabilizing ON/OFF operations and reducing the switching time.

In the semiconductor switching element 20, out of the plurality of second terminals 12A, 12B, and 12C, the terminal (the second terminal 12C) whose path length to the third semiconductor portion 18A is shortest is coupled to the driving circuit-side conducting path 52. As a result of the terminal (the second terminal 12C) whose path length to the third semiconductor portion 18A is shortest, out of the plurality of second terminals 12A, 12B, and 12C, is thus coupled to the driving circuit-side conducting path 52, the path from the terminal (the second terminal 12C) coupled to the driving circuit-side conducting path 52 to the third semiconductor portion 18A is made shorter. Accordingly, this semiconductor switching device 10 is configured so that parasitic inductance in the path from the second terminal 12C coupled to the driving circuit-side conducting path 52 to the third semiconductor portion 18A is further reduced, and this configuration is further advantageous in stabilizing ON/OFF operations and reducing the switching time.

The number of terminals coupled to the second conducting path 62, out of the plurality of second terminals 12A, 12B, and 12C, is greater than the number of terminals coupled to the driving circuit-side conducting path 52. In this semiconductor switching device 10, a back electromotive force that derives from parasitic inductance is reduced in the path between the second semiconductor portion 15A and the driving circuit-side conducting path 52, and meanwhile, parasitic inductance can be further reduced between the second semiconductor portion 15A and the second conducting path 62.

In the power supply device 2, the voltage conversion unit 3 has the high-side switching unit and the low-side switching unit that are connected to each other in series between the one conducting path 71 and the ground 93. The high-side switching unit is constituted by the semiconductor switching device 10. Since a problem of an increase in the switching time due to parasitic inductance is likely to occur in the high-side switching unit, application of the above-described semiconductor switching device 10 to the high-side switching unit is further effective.

### Other Embodiments

The present invention is not limited to the embodiment described in the above description and the drawings, and for example, the following embodiments are also encompassed in the technical scope of the present invention. The above embodiment and the following embodiments can be combined as long as no inconsistency occurs.

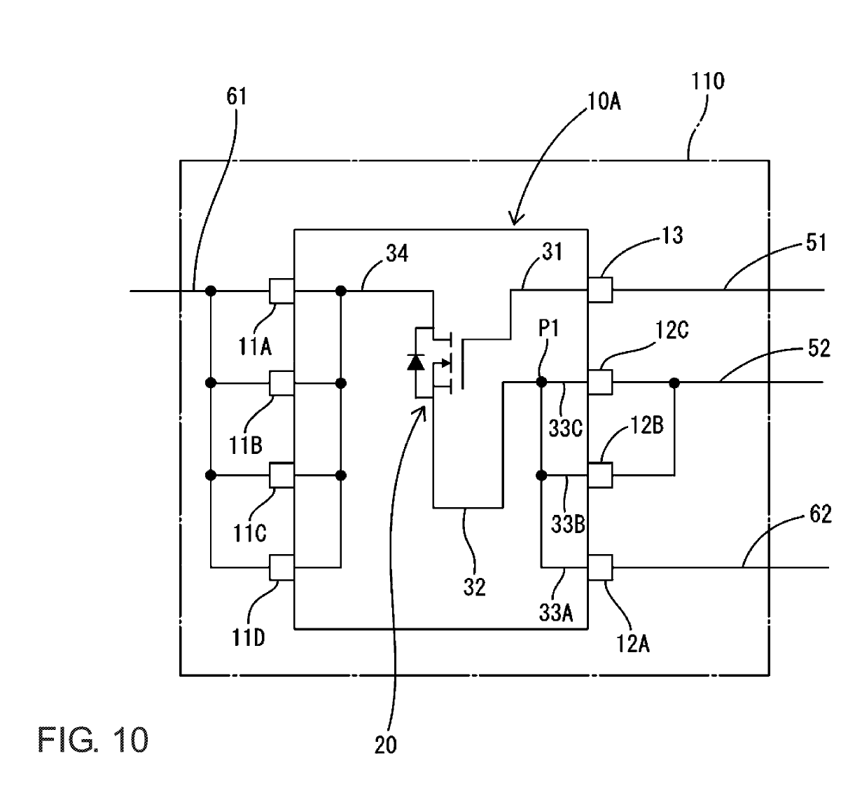

The configuration in FIG. 1 may also be changed as shown in FIG. 10. In a semiconductor switching device 110 shown in FIG. 10, only the second terminal 12A is coupled to the second conducting path 62, and the second terminals 12B and 12C are coupled to the driving circuit-side conducting path 52. In the configuration in FIG. 10, the number of terminals coupled to the driving circuit-side conducting path 52, out of the plurality of second terminals 12A, 12B, and 12C, is greater than the number of terminals coupled to the second conducting path 62. In this semiconductor switching device 110, a back electromotive force that derives from parasitic inductance is reduced by shortening a path through which a large current flows in the path between the second semiconductor portion 15A (FIG. 4) and the driving circuit-side conducting path 52, as well as the configuration in which more second terminals are coupled to the driving circuit-side conducting path 52 can further reduce parasitic inductance between the second semiconductor portion 15A and the driving circuit-side conducting path 52. Note that the semiconductor switching device 110 shown in FIG. 10 differs from the semiconductor switching device 10 of Embodiment 1 only in the coupling structure between the second conducting path 62 and the driving circuit-side conducting path 52, and is the same as the semiconductor switching device 10 as for the remaining configurations. For example, a semiconductor package 10A in the semiconductor switching device 110 has the same configuration as that of the semiconductor package 10A of the semiconductor switching device 10 shown in FIG. 1 and other diagrams.

In the semiconductor switching device in any of the above embodiment and modifications thereof, the semiconductor switching element is not limited to an N-channel MOSFET, and may be changed to a semiconductor switching element that is configured as a P-channel MOSFET, or may be an FET other than a MOSFET, or may be a semiconductor switching element such as a bipolar transistor or an IGBT.

In the semiconductor switching device in any of the above embodiment and modifications thereof, the number of first terminals may also be one or more except four. If there are more than one first terminals, all of them may be coupled to the first conducting path, or only some of them may be coupled to the first conducting path. The number of second terminals may also be more than one except three, and the number of third terminals may also be two or more.

The above embodiment has described an example in which a semiconductor package included in the semiconductor switching device 10 is the semiconductor package 10A that is configured as an SOP, but the semiconductor switching device in any of the above embodiment and modifications thereof may include a semiconductor package that has a known package structure other than an SOP.

The above embodiment has described an example in which the semiconductor switching device 10 is applied to the power supply device 2 that is configured as a step-down DCDC converter, but the semiconductor switching device in any of the above embodiment and modifications thereof may also be applied to a step-up DCDC converter, or may also be applied to a step-up/step-down DCDC converter, or may also be applied to a unidirectional DCDC converter that converts a voltage input from one side and outputs the converted voltage to the other side, or may also be applied to a bidirectional DCDC converter. The circuitry to which the semiconductor switching device 10 is applied is not limited either, and the semiconductor switching device 10 may also be applied to an H-bridge DCDC converter, for example. For example, by changing the arrangement of the power supply device 2 to a known step-up-type arrangement so that the inductor 3A is arranged at the position of the semiconductor switching device 10 shown in FIG. 6, and the semiconductor switching device 10 is arranged at the position of the inductor 3A shown in FIG. 6, the power supply device 2 can be configured as a step-up DCDC converter that boosts a voltage input to the one conducting path 71 and output the boosted voltage to the other conducting path 72. In this case, a connection structure similar to that of the semiconductor switching device 10 shown in FIGS. 1 to 5 can also be applied to all of the switching units that are provided in series between the other conducting path 72 and the ground 93.

The power supply device in any of the above embodiment and modifications thereof can employ diode rectification. For example, in the power supply device 2 shown in FIG. 6, a diode may be employed as the low-side switching unit to form a DCDC converter that uses diode rectification. In the case of using a diode on the high side and a switching unit on the low side in a step-up DCDC converter or the like, the semiconductor switching device in any of the above embodiment and modifications thereof may be applied to the low-side switching unit.

Although the above embodiment has described a single-phase DCDC converter as an example, the semiconductor switching device in any of the above embodiment and modifications thereof may also be applied to a multi-phase DCDC converter.

Although the above embodiment has omitted power units, loads, and so on that are connected to the conducting paths 71 and 72, various devices and electronic components can be connected to the conducting paths 71 and 72 in any of the above embodiment and modifications thereof.

### LIST OF REFERENCE NUMERALS

1: In-vehicle power supply device
3: Voltage conversion unit
5B: In-vehicle driving circuit
10, 40, 110: In-vehicle semiconductor switching device
11A, 11B, 11C, 11D: First terminal
12A, 12B, 12C: Second terminal
13: Third terminal
14A: First semiconductor portion
15A: Second semiconductor portion
16A: Input portion
18A: Third semiconductor portion
20: Semiconductor switching element
32: Shared conducting path
33A, 33B, 33C: Branch conducting path
52, 54: Driving circuit-side conducting path
61, 63: First conducting path
62, 64: Second conducting path
71: One conducting path
72: Another conducting path
93: Ground

What is claimed is:

1. An in-vehicle semiconductor switching device that is turned ON and OFF by an ON signal and an OFF signal that is output from an in-vehicle driving circuit, and is switched between an ON state and an OFF state, at a position between a first conducting path and a second conducting path, the semiconductor switching device comprising:
a semiconductor switching element comprising a first semiconductor portion made of a semiconductor material, a second semiconductor portion arranged at a position different from the position of the first semiconductor portion and made of a semiconductor material, and an input portion to which the ON signal and the OFF signal are input from the driving circuit, wherein the semiconductor switching element enters the ON state if the ON signal is input to the input portion, and enters the OFF state if the OFF signal is input to the input portion;
at least one first terminal electrically connected to the first semiconductor portion;
a plurality of second terminals electrically connected to the second semiconductor portion; and
at least one third terminal electrically connected to the input portion,
wherein the first terminal is connected to the first conducting path, and
only some of the plurality of second terminals are coupled to the second conducting path, and at least one of the remaining second terminals is coupled to a driving circuit-side conducting path electrically connected to the driving circuit.

2. The in-vehicle semiconductor switching device according to claim 1,
wherein the plurality of second terminals are formed with the same conductive member, and are integrally coupled to each other.

3. The in-vehicle semiconductor switching device according to claim 1,
wherein the semiconductor switching element has a third semiconductor portion provided between the first semiconductor portion and the second semiconductor portion, a current flows between the first semiconductor portion and the second semiconductor portion via the third semiconductor portion if the ON signal is input to the input portion, and no current flows via the third semiconductor portion if the OFF signal is input to the input portion, and
out of the plurality of second terminals, a terminal whose path length to the third semiconductor portion is shortest is coupled to the driving circuit-side conducting path.

4. The in-vehicle semiconductor switching device according to claim 1,
wherein, out of the plurality of second terminals, a number of terminals coupled to the second conducting path is greater than a number of terminals coupled to the driving circuit-side conducting path.

5. The in-vehicle semiconductor switching device according to claim 1,
wherein, out of the plurality of second terminals, a number of terminals coupled to the driving circuit-side conducting path is greater than a number of terminals coupled to the second conducting path.

6. An in-vehicle power supply device comprising:
the in-vehicle semiconductor switching device according to claim 1; and
a voltage conversion unit that boosts or drops a voltage applied to one conducting path and applies the boosted or dropped voltage to another conducting path, in accordance with a switching operation of one or more switching units,
wherein at least one of the switching units is constituted by the semiconductor switching device.

7. The in-vehicle power supply device according to claim 6,
wherein the voltage conversion unit is configured so that a high-side switching unit, out of the switching units, is connected to a low-side switching unit, out of the switching units, or a diode, to each other in series between a ground and one of the one conducting path and the other conducting path, and
the high-side switching unit is constituted by the semiconductor switching device.
